(19) United States
(12) Patent Application Publication
(10) Pub. No.: US 2025/0338560 A1
(43) Pub. Date: Oct. 30, 2025

(54) METHOD TO ACHIEVE LOW CONTACT RESISTANCE AND THE STRUCTURES THEREOF

(71) Applicant: Taiwan Semiconductor Manufacturing Co., Ltd., Hsinchu (TW)

(72) Inventors: Sih-Jie Liu, Hsinchu (TW); Min-Tsang Li, Hsinchu (TW); Wen-Yen Chen, Hsinchu (TW); Chia-Cheng Chen, Hsinchu (TW); Chien-Hao Chen, Chuangwei Township (TW)

(21) Appl. No.: 19/261,139

(22) Filed: Jul. 7, 2025

Related U.S. Application Data
(63) Continuation of application No. 18/816,317, filed on Aug. 27, 2024.
(60) Provisional application No. 63/638,497, filed on Apr. 25, 2024.

(51) Int. Cl. H10D 30/67; H01L 21/324; H10D 30/01; H10D 30/43; H10D 62/10; H10D 64/01; H10D 84/01; H10D 84/03; H10D 84/83

(52) U.S. Cl. CPC H10D 30/6735; H01L 21/324; H10D 30/014; H10D 30/43; H10D 30/6757; H10D 62/121; H10D 64/017; H10D 84/013; H10D 84/0135; H10D 84/038; H10D 84/83

(57) ABSTRACT

A method includes forming a transistor over a semiconductor substrate, which includes forming a source/drain region through an epitaxy process. The method further includes performing a backside thinning process to thin the semiconductor substrate, etching the semiconductor substrate to form a contact opening, wherein a back surface of the source/drain region is exposed through the contact opening, performing an amorphization implantation process through the contact opening to generate an amorphous region in the source/drain region, and forming a silicide region on the source/drain region.

### PRIORITY CLAIM AND CROSS-REFERENCE

This application is a continuation of U.S. patent application Ser. No. 18/816,317, filed on Aug. 27, 2024, which application claims the benefit of the following provisionally filed U.S. Patent application: application Ser. No. 63/638,497, filed on Apr. 25, 2024, and entitled “METHOD TO ACHIEVE LOW CONTACT RESISTANCE OF SUPER POWER RAIL,” which applications are hereby incorporated herein by reference.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (for example, transistors, diodes, resistors, capacitors, etc.) through continual reduction in minimum feature size, which allows more components to be integrated into a given area. As the minimum feature sizes are reduced, however, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-5A, 5B, 6A, 6B, 7A, 7B, 8A, 8B, 9A, 9B, 10A, 10B, 11A, 11B through 21 illustrate the views of intermediate stages in the formation of a transistor and a backside connection structure in accordance with some embodiments.

FIG. 22 illustrates a process flow for forming a transistor and a backside connection structure in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Gate-All-Around (GAA) transistor, a backside connection structure connecting to the source/drain regions of the GAA transistor, and the methods of forming the same are provided. In accordance with some embodiments, A GAA transistor is formed. A contact opening is formed from a backside of the GAA transistor to reveal a (epitaxy) source/drain region. A solid phase epitaxy regrowth (SPER) process is then performed, which may include an amorphization implantation process and a doping implantation process. The amorphization implantation process is performed so that the source/drain region is amorphized. The doping implantation process introduces more dopant into the source/drain region. An anneal process may then be performed to recrystallize the amorphous portion of the source/drain region.

Through the SPER process, the dopant solubility is increased. The thickness of the resulting silicide may also be increased to reduce the resistance of the silicide regions. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

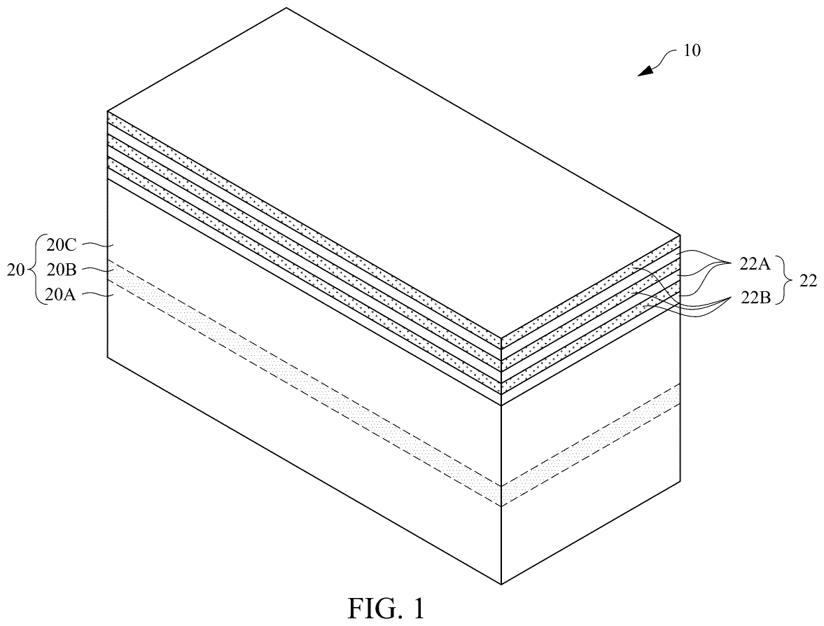

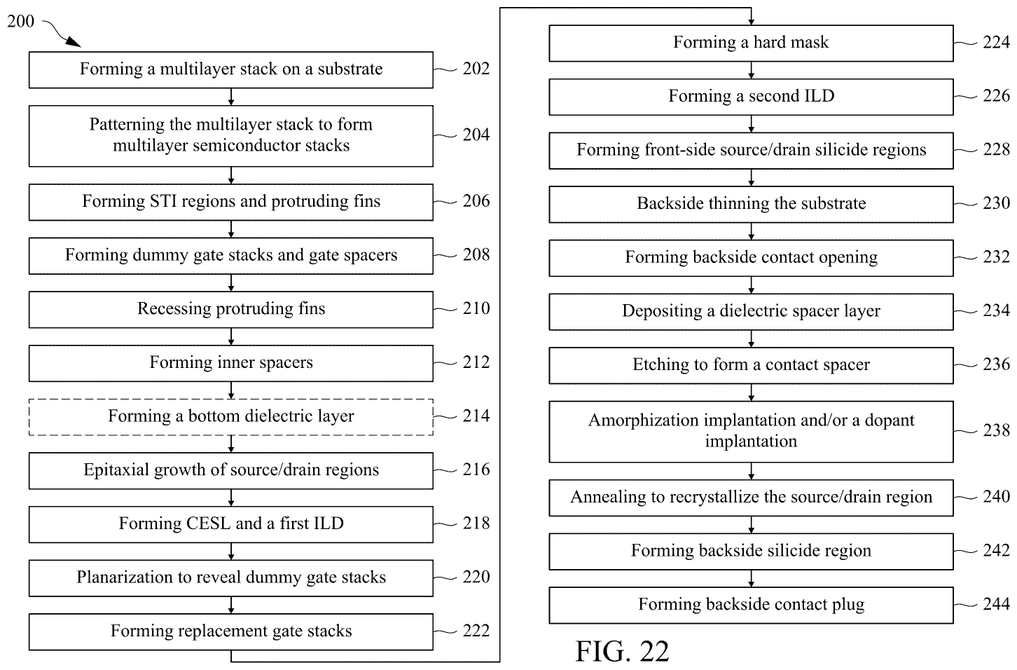

FIGS. 1 through 21 illustrate the views of intermediate stages in the formation of a transistor and a backside connection structure in accordance with some embodiments of the present disclosure. The corresponding processes are also reflected schematically in the process flow shown in FIG. 22.

Referring to FIG. 1, a perspective view of wafer 10 is shown. Wafer 10 includes a multilayer structure comprising multilayer stack 22 on substrate 20. In accordance with some embodiments, substrate 20 is a bulk substrate formed of a homogeneous semiconductor material such as silicon. In accordance with alternative embodiments, as shown in FIG. 1, substrate 20 is a composite substrate having an SOI structure. The SOI structure may include semiconductor layers 20A and 20C, which may be silicon layers, and dielectric layer 20B, which may be formed of or comprise silicon nitride, silicon oxide, or the like.

In accordance with some embodiments, multilayer stack 22 is formed through a series of deposition processes for depositing alternating materials. The respective process is illustrated as process 202 in the process flow 200 as shown in FIG. 22. In accordance with some embodiments, multilayer stack 22 comprises first layers 22A formed of a first semiconductor material and second layers 22B formed of a second semiconductor material different from the first semiconductor material.

In accordance with some embodiments, first layers 22A may be formed of or comprise SiGe, Ge, Si, GaAs, InSb, GaSb, InAlAs, InGaAs, GaSbP, GaAsSb, or the like. Second layers 22B may also be formed of a material selected from Si, SiGe, Ge, GaAs, InSb, GaSb, InAlAs, InGaAs, GaSbP, GaAsSb, combinations of these, or the like, with the second semiconductor material being different from the first semiconductor material of first layers 22A. For example, in accordance with some embodiments, the first layers 22A are silicon germanium layers, while the second layer 22B may be formed of silicon, or vice versa.

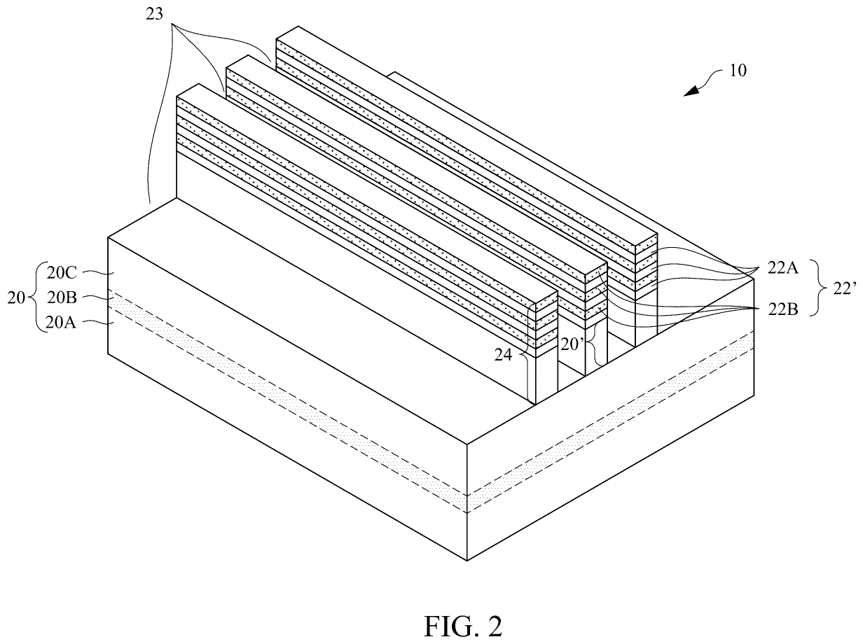

Referring to FIG. 2, multilayer stack 22 and a portion of the underlying substrate 20 are patterned in an etching process(es), so that trenches 23 are formed. The respective process is illustrated as process 204 in the process flow 200 as shown in FIG. 22. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and Semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

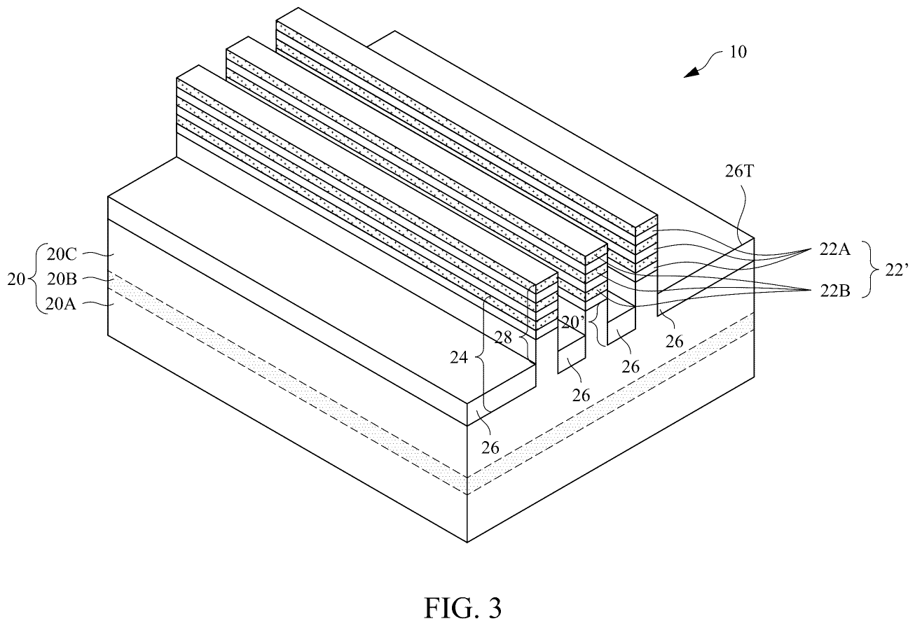

FIG. 3 illustrates the formation of isolation regions 26, which are also referred to as Shallow Trench Isolation (STI) regions throughout the description. The respective process is illustrated as process 206 in the process flow 200 as shown in FIG. 22. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. In accordance with alternative embodiments of the present disclosure, the recessing of STI regions 26 is performed through a wet etching process. The etching chemical may include HF, for example.

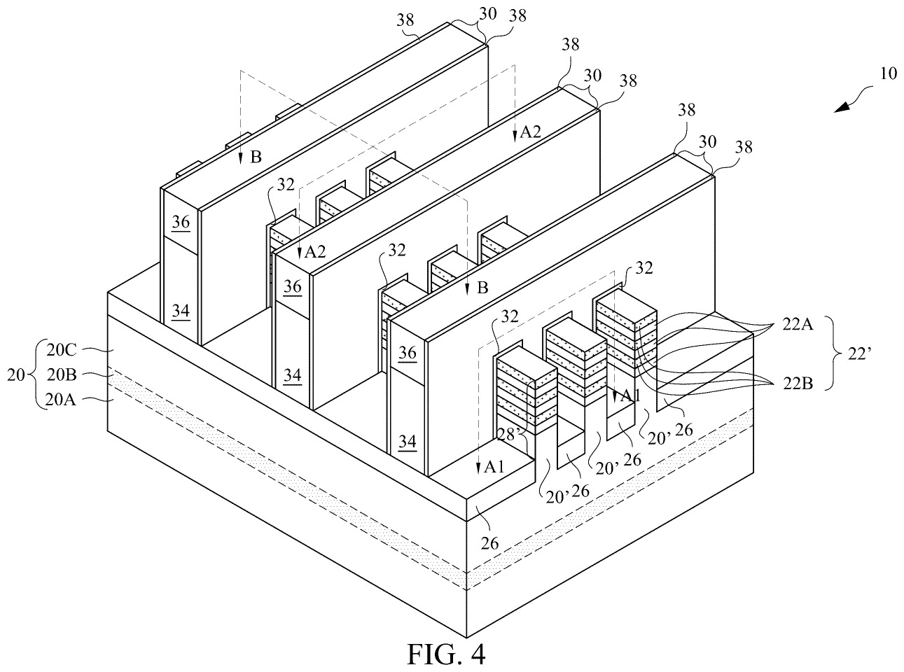

Referring to FIG. 4, dummy gate stacks 30 and gate spacers 38 are formed on the top surfaces and the sidewalls of (protruding) fins 28. The respective process is illustrated as process 208 in the process flow 200 as shown in FIG. 22. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof.

Next, gate spacers 38 are formed on the sidewalls of dummy gate stacks 30. In accordance with some embodiments of the present disclosure, gate spacers 38 are formed of a dielectric material such as silicon nitride (SiN), silicon oxide (SiO), silicon carbide (SiC), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers.

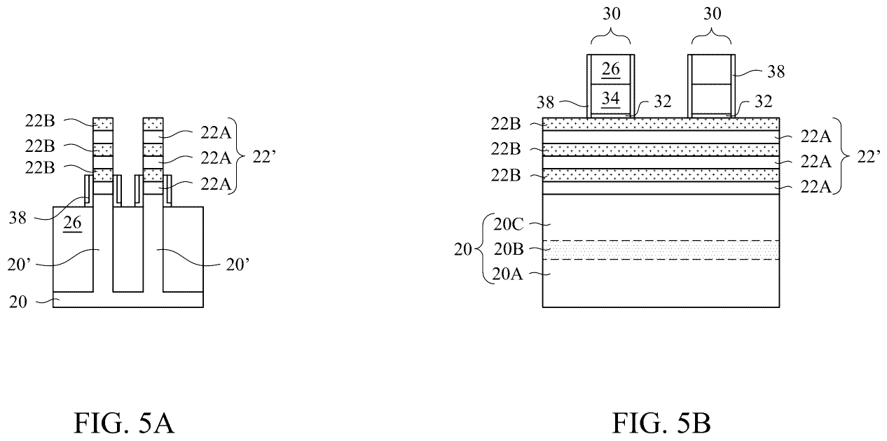

FIGS. 5A and 5B illustrate the cross-sectional views of the structure shown in FIG. 4. FIG. 5A illustrates the reference cross-section A1-A1 in FIG. 4, which cross-section cuts through the portions of protruding fins 28 not covered by gate stacks 30 and gate spacers 38, and is perpendicular to the gate-length direction. FIG. 5B illustrates the reference cross-section B-B in FIG. 4, which reference cross-section is parallel to the lengthwise directions of protruding fins 28.

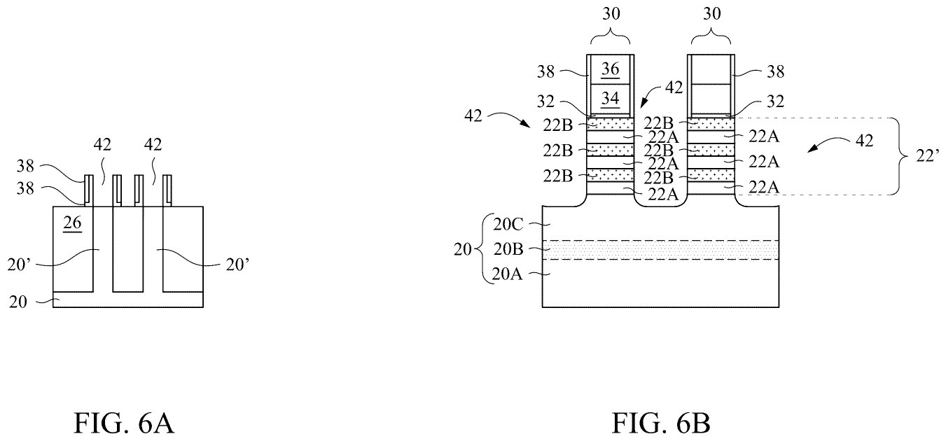

Referring to FIGS. 6A and 6B, the portions of protruding fins 28 (FIG. 4) that are not directly underlying dummy gate stacks 30 and gate spacers 38 are recessed through an etching process to form recesses 42. The respective process is illustrated as process 210 in the process flow 200 as shown in FIG. 22. The etching may be anisotropic, so that the sidewalls of multilayer semiconductor stacks 22′ facing recesses 42 are vertical and straight, as shown in FIG. 6B.

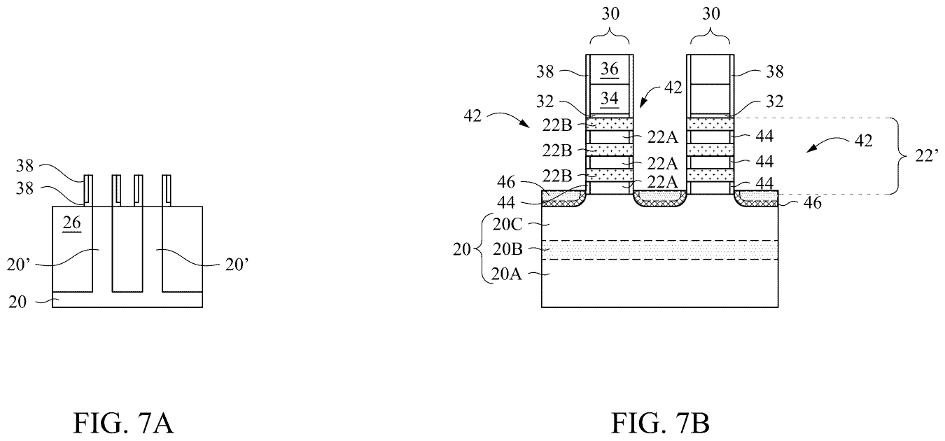

Referring to FIGS. 7A and 7B, sacrificial semiconductor layers 22A are laterally recessed to form lateral recesses, which are then filled with a dielectric material to form inner spacers 44. The respective process is illustrated as process 212 in the process flow 200 as shown in FIG. 22.

In accordance with alternative embodiments, the lateral recessing of sacrificial semiconductor layers 22A is performed through an isotropic dry etching process or a combination of a dry etching process and a wet etching process. The formation of inner spacers 44 includes depositing a conformal dielectric layer, which extends into the lateral recesses (FIG. 7B). Next, an etching process (also referred to as a spacer trimming process) is performed to trim the portions of the spacer layer outside of the lateral recesses, leaving the portions of the spacer layer in the lateral recesses. The remaining portions of the spacer layer are referred to as inner spacers 44.

FIGS. 7A and 7B further illustrates the formation of dielectric layers 46 in accordance with some embodiments. The respective process is illustrated as process 214 in the process flow 200 as shown in FIG. 22. In accordance with alternative embodiments, the formation of the dielectric layers 46 is omitted, and the subsequently formed epitaxy regions will be in contact with substrate layer 20C. Accordingly, dielectric layers 46 (FIG. 7B) and process 214 (FIG. 22) are illustrated as being dashed to indicate that they may be, or may not be, formed. Dielectric layer 46 may comprise a silicon nitride layer, and may or may not include a silicon oxide layer underlying the silicon nitride layer.

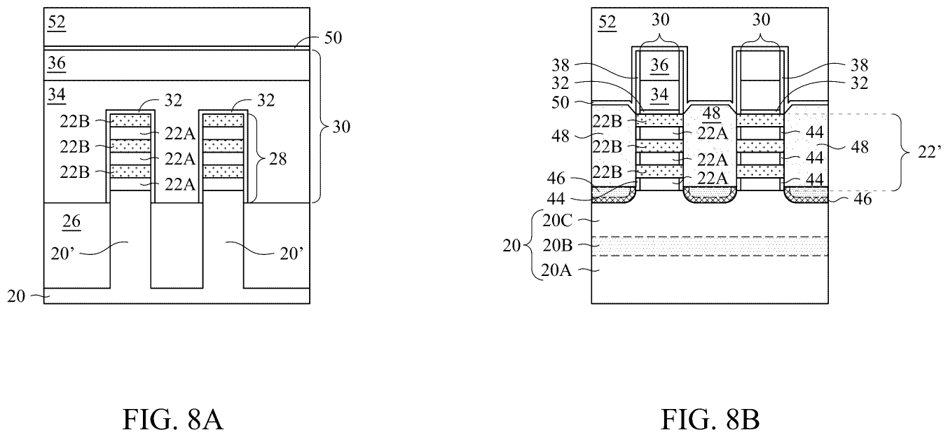

Referring to FIGS. 8A and 8B, epitaxial source/drain regions 48 are formed in recesses 42 through selective epitaxy. The respective process is illustrated as process 216 in the process flow 200 as shown in FIG. 22. Depending on whether the resulting transistor is a p-type transistor or an n-type transistor, a p-type or an n-type impurity (dopant) may be in-situ doped with the proceeding of the epitaxy. For example, when the resulting transistor is a p-type transistor, silicon germanium boron (SiGeB), silicon boron (SiB), or the like may be grown. Conversely, when the resulting transistor is an n-type transistor, silicon phosphorous (SiP), silicon carbon phosphorous (SiCP), or the like may be grown.

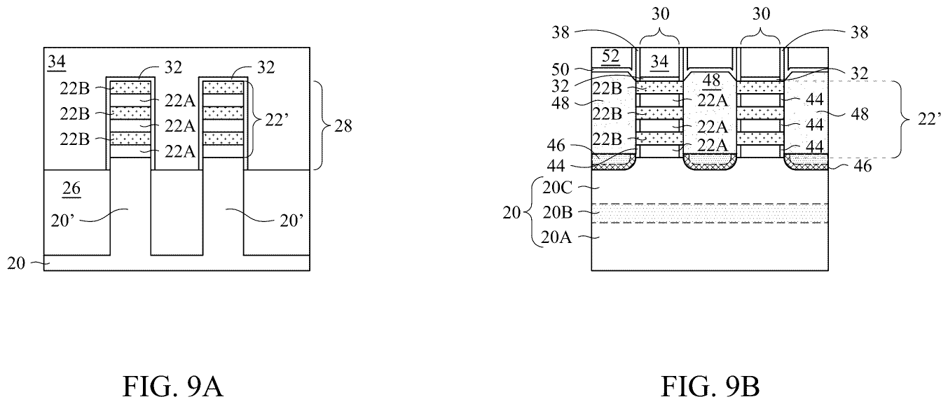

FIGS. 9A and 9B illustrate the cross-sectional views of the structure after the formation of Contact Etch Stop Layer (CESL) 50 and Inter-Layer Dielectric (ILD) 52. The respective process is illustrated as process 218 in the process flow 200 as shown in FIG. 22. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may comprise silicon-oxide, Phospho-Silicate Glass (PSG), Boro-Silicate Glass (BSG), Boron-Doped Phospho-Silicate Glass (BPSG), Undoped Silicate Glass (USG), or the like.

CESL 50 and ILD 52 are planarized through a planarization process such as a CMP process or a mechanical grinding process. The respective process is illustrated as process 220 in the process flow 200 as shown in FIG. 22. In accordance with some embodiments, the planarization process may remove hard masks 36 to reveal dummy gate electrodes 34, as shown in FIGS. 9A and 9B. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

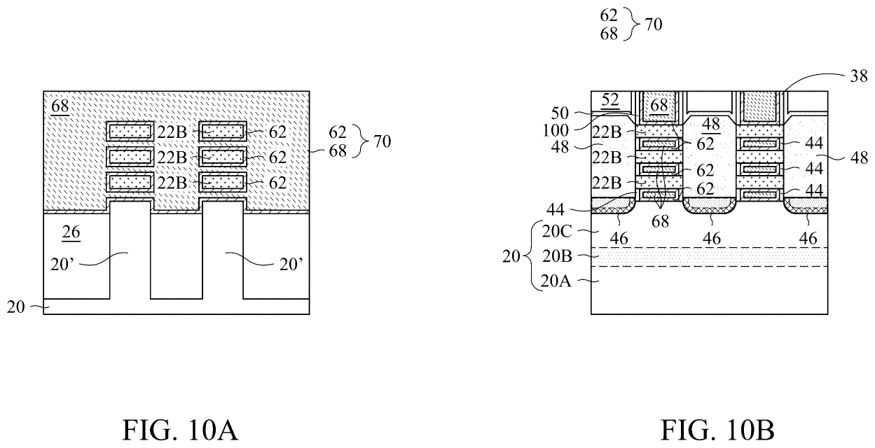

Referring to FIGS. 10A and 10B, a replacement gate process is performed, and dummy gate stacks 30 and sacrificial layers 22A are replaced with replacement gate stacks. The respective process is illustrated as process 222 in the process flow 200 as shown in FIG. 22. In accordance with some embodiments, dummy gate electrodes 34 and dummy gate dielectrics 32 (and hard masks 36, if remaining) are first removed in one or more etching processes to form recesses.

Sacrificial layers 22A are then removed to extend the recesses between nanostructures 22B. Sacrificial layers 22A may be removed by performing an isotropic etching process such as a wet etching process using etchants which are selective to remove the materials of sacrificial layers 22A, while nanostructures 22B, substrate 20, and STI regions 26 remain relatively un-etched as compared to sacrificial layers 22A.

Gate dielectrics 62 and gate electrodes 68 are formed, hence forming replacement gate stacks 70. In accordance with some embodiments, each of gate dielectric 62 includes an interfacial layer and a high-k dielectric layer on the interfacial layer. The interfacial layer may be formed of or comprises silicon oxide, which may be deposited through a conformal deposition process such as ALD or CVD, or through an oxidation process. In accordance with some embodiments, the high-k dielectric layers comprise one or more dielectric layers. For example, the high-k dielectric layer(s) may include a metal oxide or a silicate of hafnium, aluminum, zirconium, lanthanum, manganese, barium, titanium, lead, and combinations thereof.

Gate electrodes 68 may include a metal-containing material such as TiN, TaN, TiAl, TiAlC, cobalt, ruthenium, aluminum, tungsten, combinations thereof, and/or multilayers thereof. For example, gate electrodes 68 may comprise any number of layers, any number of work function layers, and possibly a filling metallic material. Gate dielectrics 62 and gate electrodes 68 also fill the spaces between adjacent ones of nanostructures 22B, and fill the spaces between the bottom ones of nanostructures 22B and the underlying substrate strips 20′. After the filling of the recesses, a planarization process such as a CMP process or a mechanical grinding process is performed to remove the excess portions of the gate dielectrics and the material of gate electrodes 68, which excess portions are over the top surface of ILD 52. Gate electrodes 68 and gate dielectrics 62 are collectively referred to as gate stacks 70 of the resulting transistors.

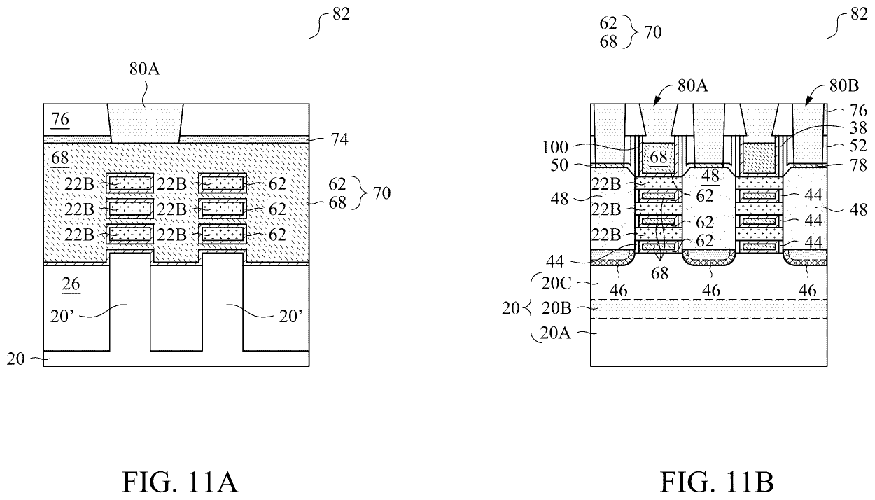

In the processes shown in FIGS. 11A and 11B, gate stacks 70 are recessed, so that recesses are formed directly over gate stacks 70 and between opposing portions of gate spacers 38. A gate mask 74 comprising one or more layers of dielectric material, such as silicon nitride, silicon oxynitride, or the like, is filled in each of the recesses, followed by a planarization process to remove excess portions of the dielectric material extending over ILD 52. The respective process is illustrated as process 224 in the process flow 200 as shown in FIG. 22.

As further illustrated by FIGS. 11A and 11B, ILD 76 is deposited over ILD 52 and over gate masks 74. The respective process is illustrated as process 226 in the process flow 200 as shown in FIG. 22. An etch stop layer (not shown) may be (or may not be) deposited before the formation of ILD 76. In accordance with some embodiments, ILD 76 is formed through FCVD, CVD, PECVD, or the like. ILD 76 is formed of a dielectric material, which may be selected from silicon oxide, PSG, BSG, BPSG, USG, or the like.

ILD 76, ILD 52, CESL 50, and gate masks 74 are then etched to form recesses (occupied by contact plugs 80A and 80B) exposing surfaces of source/drain regions 48 and/or gate stacks 70. The recesses may be formed through etching using an anisotropic etching process, such as RIE, NBE, or the like.

After the recesses are formed, (front-side) silicide regions 78 are formed over source/drain regions 48. The respective process is illustrated as process 228 in the process flow 200 as shown in FIG. 22. Source/drain contact plugs 80B are then formed over silicide regions 78, and are referred to as front-side source/drain contact plugs 80B. Also, contact plugs 80A (may also be referred to as gate contact plugs) are also formed in the recesses, and are over and contacting gate electrodes 68. Transistor 82 is thus formed. In subsequent processes, some upper features such as ILDs, low-k dielectric layers, metal lines and vias, and the like, may be formed.

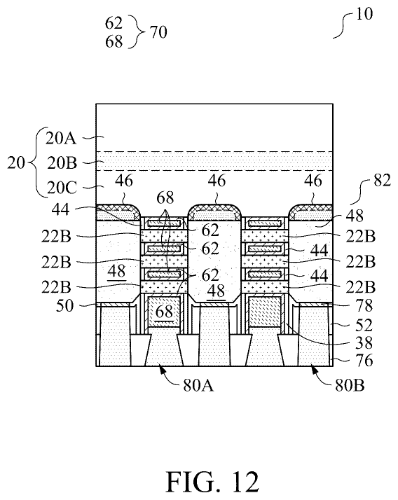

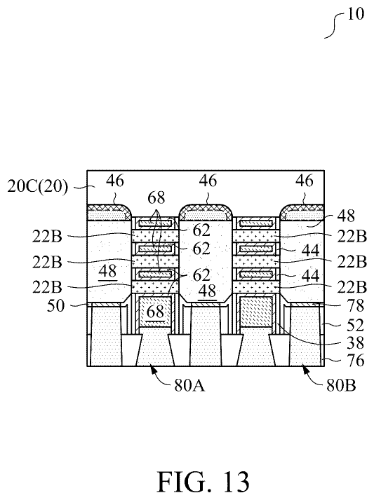

FIG. 12 illustrates an upside-down view of the structure shown in FIG. 11B. Next, substrate 20 is thinned from the backside of wafer 10. The respective process is illustrated as process 230 in the process flow 200 as shown in FIG. 22. In accordance with some embodiments, substrate 20 includes semiconductor layers 20A and 20C, and dielectric layer 20B between semiconductor layers 20A and 20C. The thinning process may be performed through CMP and/or etching, with dielectric layer 20B being used as a CMP stop layer and/or an etch stop layer. Dielectric layer 20B may then be removed, exposing semiconductor layer 20C, as shown in FIG. 13. Semiconductor layer 20C, which is a remaining portion of the thinned semiconductor substrate 20, and hence may also be referred to as semiconductor substrate 20.

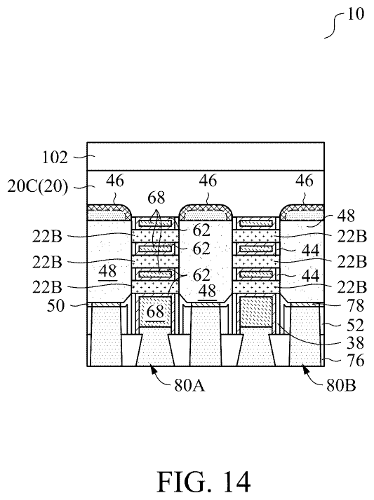

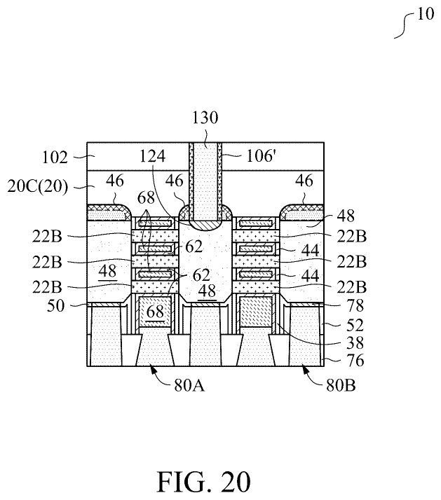

FIG. 14 illustrates the formation of dielectric layer 102 in accordance with some embodiments. Dielectric layer 102 may comprise a dielectric material such as silicon oxide, silicon nitride, silicon oxynitride, or the like. In accordance with alternative embodiments, dielectric layer 102 is not formed at this time. Rather, dielectric layer 102 may be formed after the formation of backside contact plug 130 (FIG. 20).

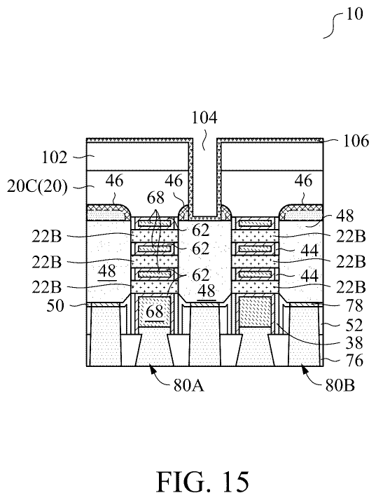

Referring to FIG. 15, contact opening 104 is formed. The respective process is illustrated as process 232 in the process flow 200 as shown in FIG. 22. The formation process includes forming an etching mask (such as a patterned photoresist, not shown), and etching dielectric layer 102 and semiconductor layer 20C through an opening in the etching mask. The etching mask is then removed. The etching process is performed through a dry etching process, which may be performed using an etching gas selected from fluorine (F₂), Chlorine (Cl₂), hydrogen chloride (HCl), hydrogen bromide (HBr), Bromine (Br₂), C₂F₆, CF₄, SO₂, the mixture of HBr, Cl₂, and O₂, or the mixture of HBr, Cl₂, O₂, and CH₂F₂ etc. The etching process is stopped on source/drain region 48. In accordance with some embodiments in which dielectric layer 46 is formed, dielectric layer 46 is also etched-through.

Further referring to FIG. 15, dielectric spacer layer 106 is deposited to extend into contact opening 104, and on the sidewalls of semiconductor layer 20C. The respective process is illustrated as process 234 in the process flow 200 as shown in FIG. 22. Dielectric spacer layer 106 also has a bottom portion contacting source/drain region 48. In accordance with some embodiments, dielectric spacer layer 106 is formed using a conformal deposition process such as CVD or ALD. Dielectric spacer layer 106 may comprise silicon oxide, silicon nitride, silicon oxynitride, silicon oxy carbo-nitride, or the like. Dielectric spacer layer 106 may also have a dielectric constant (k value) greater than 3.9, so that it has good isolation ability. The candidate materials include AlₓO_{y}, HfO₂, or the like. The thickness of dielectric spacer layer 106 may be in the range between about 2 nm and about 6 nm, for example.

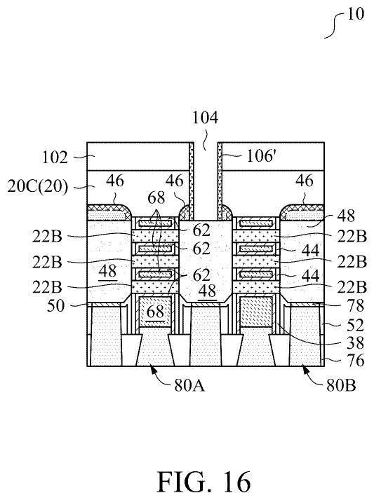

Referring to FIG. 16, an anisotropic etching process is performed, so that the horizontal portions of dielectric spacer layer 106 are removed, and the vertical portions of dielectric spacer layer 106 inside contact opening 104 are left to form contact spacer 106′. The respective process is illustrated as process 236 in the process flow 200 as shown in FIG. 22. Contact spacer 106′ may form a ring encircling opening 104 when viewed from the top of wafer 10.

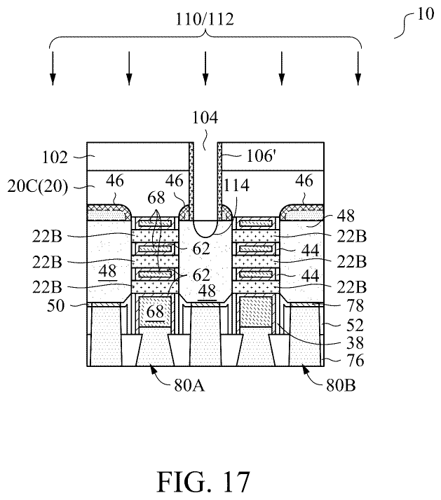

Next, as shown in FIG. 17, an amorphization implantation process 110 and/or a doping implantation process 112 are performed to implant a dopant(s) into source/drain region 48. The respective process is illustrated as process 238 in the process flow 200 as shown in FIG. 22. The amorphization implantation process 110 results in a portion of source/drain region 48 to be converted to amorphous region 114. The doping implantation process 112 introduces into the implanted region an extra dopant that is of the same conductivity type as the dopant of source/drain region 48, hence results in the increase in the doping concentration, at least in the backside portion of the source/drain region 48.

Either one or both of the amorphization implantation process 110 and the doping implantation process 112 may be performed, and accordingly, notation “110/112” is used to refer to either one or both of the amorphization implantation process 110 and the doping implantation process 112.

In accordance with some embodiments, the amorphization implantation process 110 may be performed by implanting a dopant (referred to as amorphization dopant hereinafter), which may include a group III element, a group IV element, a group V element, and/or an inert gas. The group III element may include B, Al, Ga, and/or the like. The group IV element may include C, Si, Ge, and/or the like. The group V element may include P, As, Sb, and/or the like. When a group III element or a group IV element is implanted, the implanted element may be of the same conductivity type as that of source/drain region 48, or may be of an opposite conductivity type than source/drain region 48. The inert gas may include He, Ar, Xe, and/or the like.

In the amorphization implantation process 110, the implantation energy may be in the range between about 0.3 keV and about 60 keV. The dosage of the amorphization dopant may be greater than 1E13 cm². The wafer temperature in the implantation may be in the range between about −150°° C. and about 500° C.

In accordance with some embodiments, the doping implantation process 112 may be performed by implanting a dopant (referred to as extra source/drain dopant hereinafter) of a same conductivity type as that of source/drain region 48. For example, when source/drain region 48 is a p-type region, the extra source/drain dopant may include B, Al, Ga, In, and/or the like. When source/drain region 48 is an n-type region, the extra source/drain dopant may include P, As, Sb, and/or the like.

The implantation energy may be in the range between about 0.3 keV and about 60 k eV. The dosage may be equal to or lower than the dosage of the amorphization implantation process 110, for example, by one order or more. For example, the dosage of the doping implantation process 112 may be greater than 1E13 cm². The wafer temperature in the doping implantation process 112 may be the same as during the amorphization implantation process 110, for example, in the range between about −150° C. and about 500° C.

In accordance with some embodiments, both of amorphization implantation process 110 and doping implantation process 112 are performed, and the amorphization implantation process 110 is performed before the doping implantation process 112. Performing amorphization implantation process 110 first may reduce the channeling of the subsequently implanted ions during the doping implantation process 112, and the implanted n-type or p-type dopant is more concentrated.

In accordance with alternative embodiments, both of amorphization implantation process 110 and doping implantation process 112 are performed, and the amorphization implantation process 110 is performed after the doping implantation process 112. Performing doping implantation process 112 first makes it possible and easier (through ion channeling) to deliver the extra source/drain dopant to desirable locations such as source/drain extension regions.

In accordance with yet alternative embodiments, the amorphization implantation process 110 is performed, while the doping implantation process 112 is not performed. In accordance with yet alternative embodiments, the doping implantation process 112 is performed, while the amorphization implantation process 110 is not performed. Accordingly, there are at least four combinations for the amorphization implantation process 110 and/or doping implantation process 112.

In accordance with yet alternative embodiments, both of the amorphization implantation process 110 and the doping implantation process 112 are combined as one implantation process, for example, by co-implanting an n-type dopant (when source/drain region 48 is of n-type) or p-type dopant (when source/drain region 48 is of p-type) along with a group IV dopant and/or an inert gas for the amorphization of the implanted portion. The n-type dopant (when source/drain region 48 is of n-type) or p-type dopant (when source/drain region 48 is of p-type) may also be co-implanted along with a p-type dopant or an n-type dopant that is of an opposite conductivity type than the conductivity type of the source/drain region 48.

The isotope difference may be used to determine whether a backside implantation process has been performed to introduce an extra source/drain dopant, or whether all of the source/drain dopant is introduced through epitaxy without through implantation. For example, the boron introduced through in-situ doping during the epitaxy of source/drain region 48 includes about 20 percent isotope 10B and about 80 percent isotope ¹¹B. The boron introduced through implantation such as doping implantation process 112 has about 100 percent ¹¹B. Accordingly, in the implanted regions implanted by doping implantation process 112, there exists the boron introduced through epitaxy and the boron introduced through the doping implantation process 112. Accordingly, the isotope ¹¹B in the implanted region will be higher than 80 percent and lower than 100 percent (or equal to about 100 percent if no in-situ doping is conducted). This feature may be used to determine whether doping implantation process 112 has been performed or not

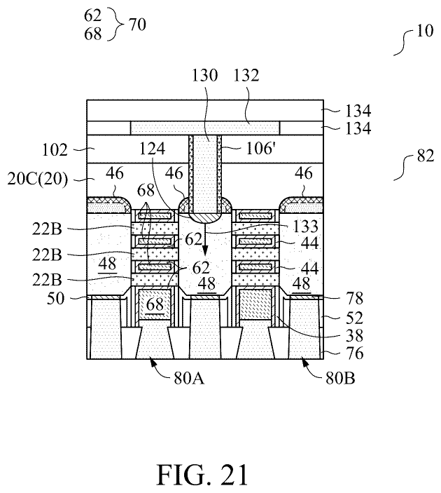

Furthermore, FIG. 21 illustrates an arrow 133, which points from the top surface of the subsequently formed silicide region 124 to a middle level between the top surface of silicide region 124 and the bottom surface of source/drain region 48. In the path represented by arrow 133, the percentage of isotope ¹¹B may have a peak in an intermediate level of arrow 133, and the percentage of isotope ¹¹B may gradually reduce from the position of the peak in directions going up and going down.

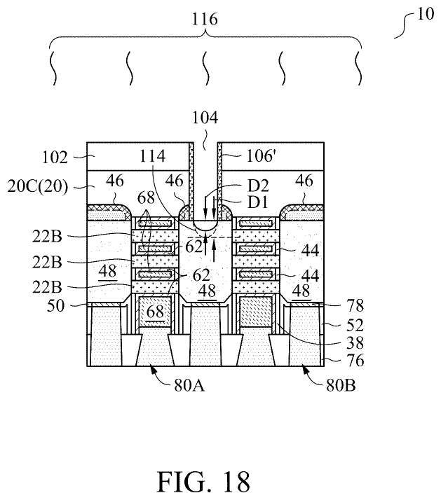

Referring to FIG. 18, an anneal process 116 is performed. The respective process is illustrated as process 240 in the process flow 200 as shown in FIG. 22. The anneal process 116 may be performed through rapid thermal anneal, milli-second anneal, micro-second anneal, flash anneal, laser anneal, or the like. During the anneal process 116, the temperature of wafer 10 and source/drain regions 48 are controlled to be not too high to prevent the damage of epitaxy source/drain regions 48. For example, in the anneal process 116, the temperature of source/drain regions 48 may be in the range between about 350° C. and about 450° C. During the anneal process 116, source/drain regions 48 remain to be solid and is not melted.

Through the progress of the anneal process 116, re-crystallization occurs, and the re-crystallization propagates from lower portion of amorphous region 114 joining the crystalline portion of source/drain region 48 into upper portions. The amorphization implantation process 110 and the re-crystallization are collectively referred to as a solid phase epitaxy regrowth (SPER) process. The solubility limit of the n-type or p-type dopant, which is the maximum concentration that can be achieved in equilibrium with its host lattice in source/drain region 48, is increased through the SPER process, and hence the concentration of the activated dopant may be advantageously increased.

In accordance with some embodiments, the anneal process 116 is stopped before the top portion of amorphous region 114 is recrystallized (partial crystallization). The remaining portion of the amorphous region 114 is shown using a solid line, and the amorphous region 114 before the anneal process 116 is shown using a dashed line. For example, the amorphous region 114 before the anneal process 116 has depth D1 (FIGS. 16 and 17), and when the anneal process 116 is stopped, the remaining portion of the amorphous region 114 has depth D2. In accordance with some embodiments, the depth ratio D2/D1 may be in the range between about 0.3 and about 0.7.

In accordance with alternative embodiments, the anneal process 116 is stopped after the entirety of amorphous region 114 is recrystallized (full crystallization). Accordingly, there are two options of performing the anneal process 116, which in combination with the at least four options of performing the amorphization implantation process 110 and the doping implantation process 112 results in at least eight options in the above-discussed processes. These options have different results. For example, the full crystallization may result in higher dopant activation rate, but the subsequently formed silicide regions 124 may be thinner and having higher resistance. The partial crystallization may result in the subsequently formed silicide regions 124 to be thicker and having lower resistance. The dopant activation rate due to the partial crystallization, however, is lower than that of the full crystallization.

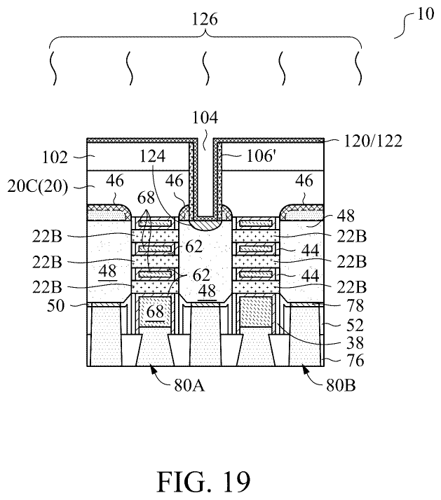

FIG. 19 illustrates the formation of (backside) source/drain silicide regions 124. The respective process is illustrated as process 242 in the process flow 200 as shown in FIG. 22. In accordance with some embodiments, metal layer 120 (which may comprise titanium, nickel, ruthenium, cobalt, tungsten, and/or the like) is deposited, for example, using Physical Vapor Deposition (PVD). Barrier layer 122, which may be a metal nitride layer such as a titanium nitride layer or a tantalum nitride layer, is then deposited over metal layer 120. An annealing process 126 is then performed to react metal layer 120 with the silicon (and germanium, if any) in source/drain region 48. Source/drain silicide region 124 is thus formed. The annealing process 126 may be performed through Rapid Thermal Anneal (RTA), furnace anneal, or the like.

In accordance with some embodiments, due to the amorphization implantation process 110 and the doping implantation process 112, dopant segregation may be observed at the interface between silicide region 124 and source/drain region 48. The dopant concentration (of n-type or p-type dopant, which is of the same type as source/drain region 48) may be in the range between about 0.1% and about 20%, which may be observed through Atom Probe Tomography (APT) or Electron Dispersive X-ray Spectroscopy (EDX).

In accordance with some embodiments, as aforementioned, amorphous region 114 (FIG. 18) has the top portion remaining after the anneal process 116. The amorphous silicon may enhance silicide growth due to faster silicon upper diffusion (caused by the lower activation energy of amorphous silicon than crystallize silicon). Accordingly, when partial crystallization was adopted in the SPER process, the resulting silicide region 124 formed from the amorphous region 114 may be thicker than if the silicide region is formed from the re-crystallized silicon. The resulting silicide region 124 thus has reduced resistance. In accordance with some embodiments in which super power rail (SPR) is formed on the backside of wafer 10 to connect to source/drain region 48, the resistance from the SPR to the source/drain region 48 is lowered.

Barrier layer 122 and the remaining metal layer 120 may then be removed. Next, as shown in FIG. 20, (backside source/drain) contact plug 130 is formed to fill contact opening 104 and to electrically connect to silicide regions 124. The respective process is illustrated as process 244 in the process flow 200 as shown in FIG. 22. In accordance with some embodiments, the formation of contact plug 130 may include forming a barrier layer, which may comprise titanium nitride, tantalum nitride, or the like. Next, a metallic material is deposited over and in contact with the barrier layer. The metallic material may include tungsten, cobalt, or the like. A planarization process such as a CMP process or a mechanical grinding process is then performed to remove excess portions of barrier layer and the metallic material.

FIG. 21 illustrates more backside features including metal line 132 and dielectric layers 134. Metal line 132 may be a SPR that carries power (VDD or VSS), and is used to provide power from the backside of the wafer 10 (and the respective device die sawed from wafer 10) to transistor 82. As may be realized from FIG. 21, through the partial crystallization process, the thickness of silicide region 124 is reduced, and the resistance is reduced. The resistance for providing power from metal line 132 to transistor 82 is reduced.

The embodiments of the present disclosure have some advantageous features. By performing backside implantation, amorphization, and/or partial crystallization, the dopant activation rate in source/drain regions is increased. The resistance of backside source/drain silicide regions is reduced. The embodiments may also reduce the number of voids at the interface between the epitaxy source/drain region and the silicide regions, and the percentages of voids per source/drain region may be reduced to lower than 10 percent.

In accordance with some embodiments of the present disclosure, a method comprises forming a transistor over a semiconductor substrate, the forming the transistor comprising forming a source/drain region through an epitaxy process; performing a backside thinning process to thin the semiconductor substrate; etching the semiconductor substrate to form a contact opening, wherein a back surface of the source/drain region is exposed through the contact opening; performing an amorphization implantation process through the contact opening to generate an amorphous region in the source/drain region; and forming a silicide region on the source/drain region. In an embodiment, the method further comprises an anneal process to recrystallize the amorphous region.

In an embodiment, at a time the anneal process is stopped, the amorphous region is partially crystalized. In an embodiment, at a time the anneal process is stopped, the amorphous region is fully crystalized. In an embodiment, the silicide region is formed after the anneal process in an additional anneal process separate from the anneal process. In an embodiment, the method further comprises performing a doping implantation process on the source/drain region, wherein the doping implantation process is performed through the contact opening. In an embodiment, a dopant of a same conductivity type as the source/drain region is implanted by the doping implantation process.

In an embodiment, an inert element is introduced into the source/drain region by the amorphization implantation process. In an embodiment, a group-IV element is introduced into the source/drain region by the amorphization implantation process. In an embodiment, the method further comprises etching a dielectric layer that separates the semiconductor substrate from the source/drain region to extend the contact opening to the source/drain region.

In accordance with some embodiments of the present disclosure, a method comprises forming a transistor over a semiconductor substrate, the forming the transistor comprising forming a plurality of semiconductor nanostructures over the semiconductor substrate; and performing an epitaxy process to form an epitaxy region connected to the plurality of semiconductor nanostructures, wherein in the epitaxy process, a first dopant of n-type or p-type is in-situ doped into the epitaxy region; forming a contact opening extending from a back surface of the semiconductor substrate to the epitaxy region; performing an amorphization implantation process to generate an amorphous region in the epitaxy region; performing a doping implantation process to introduce a second dopant of a same conductivity type as the first dopant into the epitaxy region; and forming a contact plug to fill the contact opening.

In an embodiment, an element selected from a group-IV element is introduced into the epitaxy region by the amorphization implantation process. In an embodiment, an inert gas is introduced into the epitaxy region by the amorphization implantation process. In an embodiment, the amorphization implantation process is performed before the doping implantation process. In an embodiment, the amorphization implantation process is performed after the doping implantation process. In an embodiment, the method further comprises forming a silicide region on the epitaxy region. In an embodiment, the method further comprises an anneal process to partially recrystallize the amorphous region.

In accordance with some embodiments of the present disclosure, a method comprises forming a transistor over a semiconductor substrate, the forming the transistor comprising forming a plurality of semiconductor nanostructures over the semiconductor substrate; and performing an epitaxy process to form an epitaxy region connected to the plurality of semiconductor nanostructures; forming a contact opening from a backside of the semiconductor substrate to reveal the epitaxy region; performing an amorphization implantation process on the epitaxy region to form an amorphous region; performing a first anneal process to partially anneal the amorphous region; and forming a silicide region based on a part of the epitaxy region that is implanted by the amorphization implantation process.

In an embodiment, the method further comprises performing a second anneal process during the forming the silicide region, wherein the first anneal process and the second anneal process are separate anneal processes. In an embodiment, the method further comprises forming contact plug in the contact opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a transistor over a semiconductor substrate, the forming the transistor comprising:
forming a source/drain region through an epitaxy process;
performing a backside thinning process to thin the semiconductor substrate;
etching the semiconductor substrate to form a contact opening, wherein a back surface of the source/drain region is exposed through the contact opening;
performing an amorphization implantation process through the contact opening to generate an amorphous region in the source/drain region;
forming a silicide region on the source/drain region;
performing an anneal process to recrystallize the amorphous region; and
performing a doping implantation process on the source/drain region, wherein the doping implantation process is performed through the contact opening.
